(19) United States
(12) Patent Application Publication
(10) Pub. No.: US 2007/0024312 A1
(43) Pub. Date: Feb. 1, 2007

(54) Device and method for the testing of integrated semiconductor circuits on wafers

(75) Inventors: Klaus Rittberger, Steinheim (DE); Heinrich Wieczorek, Obereisesheim (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/493,628

(22) Filed: Jul. 27, 2006

Related U.S. Application Data
(60) Provisional application No. 60/706,037, filed on Aug. 8, 2005.

(30) Foreign Application Priority Data
Jul. 27, 2005 (DE) DE 102005035031

(51) Int. Cl. G01R 31/26

(52) U.S. Cl. 324/765

(57) ABSTRACT

A device for testing a plurality of integrated semiconductor circuits on wafers is disclosed. The device includes a support device for taking in and temperature control, particularly heating or cooling, of the wafer, a measuring board with electronic circuit units for a function check of the integrated semiconductor circuits disposed on the wafers, a test head, connected to the measuring board, with contact needles, the head which creates an electrical contact between the measuring board and the integrated semiconductor circuits, and at least one nozzle for introducing a purge gas onto the wafer surface, whereby the device is provided without a sealing enclosure and that the support device, measuring board, wafer, test head, and nozzle are exposed to the gas mixture of the atmosphere.

This nonprovisional application claims priority to Provisional Application 60/706,037 and claims priority under 35 U.S.C. § 119(a) on German Patent Application No. DE 102005035031, which was filed in Germany on Jul. 27, 2005, and which are both herein incorporated by reference.

### BACKGROUND OF THE INVENTION

1. Field of the Invention

The present invention relates to a device and a method for the testing of integrated semiconductor circuits on wafers.

2. Description of the Background Art

After integrated semiconductor circuits are fabricated, they are subjected to a function check in a test step while they are still integrated in the wafer, therefore before their dicing. The ratio of the usable number to the total number of all electronic components present on a wafer is described as “the yield” and is an important key figure for evaluating the fabrication process and the efficiency of a production line.

A device for the testing of the wafer comprises a movable support device, a so-called chuck, on which the wafer can be supported, suctioned by a vacuum pump, fixed, and moved in the x, y, and z direction. Furthermore, the device contains a measuring board, on which electronic circuits are disposed, by which the functionality of the integrated semiconductor circuits on the wafer can be tested. In each case, a test head, which has spring-loaded, hair-thin contact needles and creates the electrical contact between the measuring board and the integrated semiconductor circuits on the wafer, is disposed on the bottom of the measuring board and above a holding mechanism connected electrically conductively to said card. In this regard, the measuring board and test head are provided with an aperture into which the contact needles extend. These are adapted in their number and design to the semiconductor circuits under test and to the contact surfaces established thereby. When the wafer has been positioned with the aid of the movable support device below the contact needles of the test head where the contact surfaces lie, the support device is moved upward (z position) and the contact surfaces of the semiconductor circuits are pressed against the contact needle tips with a special contact pressure. During the contacting, the electronic circuits on the measuring board send test signals and evaluate the response signals, which come back from the individual integrated semiconductor circuits disposed on the wafer. Furthermore, voltage and current flow in the semiconductor circuits are tested during the course of the function check.

After the function of an integrated semiconductor circuit has been checked, the support device with the wafer is moved on to the next component and again contacts this component.

Typically, the contact surfaces of an electronic component on a wafer include metallic material, such as, for example, aluminum, which forms an oxide layer on its surface in air. Upon pressing of the contact needles to the contact surface, this metal oxide layer, which has a thickness of several micrometers, must be overcome; during this process, the contact needle tips in particular are mechanically stressed and therefore subject to wear, which limits their lifetime. It has become evident in practice that the tips of the contact needles oxidize or exhibit deformations after several test procedures; in particular, deposits on the contact needle tips increase the transition resistance. This greatly reduces the useful life of the contact needles or of the entire test head.

JP 2001007164A discloses a device for the testing of properties of a sample having a circuit on the surface. The device is provided with a purge gas supply system, which supplies a purge gas to the sample surface, in order to place the sample surface under a highly concentrated purge gas atmosphere. The entire device is located in a purge box, in which a purge gas atmosphere prevails and which consists of a shield case to accommodate the device and an additional pass box. In this regard, a higher internal pressure prevails in the shield case than in the pass box. With the aid of the device, the sample is to be kept under a stable highly concentrated purge gas atmosphere to prevent oxidation and condensation on the sample surface under test.

A disadvantage of the device is that the samples must be first placed in the pass box with each change to adapt the purge gas concentration there to the concentration prevailing in the shield case, and can be positioned only in another work step with consideration of the pressure conditions in the shield case. This makes the testing procedure very laborious and expensive, because the measuring times increase greatly overall.

### SUMMARY OF THE INVENTION

It is therefore an object of the present invention to increase the useful life of the contact needles and the measuring reliability of the testing device while avoiding the aforementioned disadvantages.

Accordingly, a device is provided for the testing of a plurality of integrated semiconductor circuits on wafers comprising a support device for taking in and temperature control, particularly heating or cooling of the wafer, a measuring board with electronic circuit units for a function check of the integrated semiconductor circuits disposed on the wafers, a test head, connected to the measuring board, with contact needles, the head which creates an electrical contact between the measuring board and the integrated semiconductor circuits, and at least one nozzle for introducing a purge gas onto the wafer surface, without a sealing enclosure, and that the support device, measuring board, wafer, test head, and nozzle are exposed to the gas mixture of the atmosphere. Tests by the applicant have hereby shown that with the aid of the aforementioned device extensive displacement of air occurs in the area of the wafer, even when the device is exposed overall to the effects of the normal atmosphere, particularly those of the highly reactive oxygen. Thus, both the housing and also the measuring and control instruments for controlling the internal pressure of the purge gas can be dispensed with, which results in a considerable saving of costs and materials.

In an embodiment of the invention, an inert gas, preferably nitrogen, is provided for introduction. Several advantages result simultaneously during the function check due to the displacement of the air around the testing area of the wafer. In one respect, the contact resistance on the contact surfaces of the integrated semiconductor circuits is lower, because the oxidation of the contact surfaces is greatly reduced in the contacting area. Furthermore, due to the inward flow of the gas, only very few ions and polar molecules (H₂O) are present in the area of the contact surfaces, which has an advantageous effect on the insulation properties of the surface between the contact surfaces. Basically, because of the residual conductivity present on the surface, a parallel connection of resistances during the function check results, whereby this includes the resistance at the surface between the contact surfaces under measurement and the resistance of the circuit parts under measurement in the wafer substrate. In fact, however, only the electrical properties of the circuit parts in the wafer substrate are to be analyzed. Therefore, the higher the resistance between the contact surfaces under measurement, the more likely the effect of the conductivity of the surface can be disregarded and as a result, in high-resistance measurements as well, the electrical properties of the circuit parts under measurement can be evaluated.

Tests conducted by the applicant have shown that it is also possible to achieve the aforementioned effects with the use of noble gases, instead of nitrogen.

According to a further embodiment of the invention, the purge gas is introduced parallel to the wafer surface. This introduction of the purge gas associated with a parallel arrangement of the nozzle onto the wafer surface is especially advantageous when the function check of the semiconductor circuits occurs at high temperatures. The purge gas acts in addition as a cooling agent and displaces the warm ambient air from the wafer surface.

Another further embodiment provides that the purge gas is introduced perpendicular to the wafer surface. Tests by the applicant have shown that the introduction of the purge gas perpendicular to the wafer surface is especially suitable for avoiding deposits on the contact needle tips. Furthermore, the introduction perpendicular to the wafer creates an especially high purge gas concentration on the wafer surface.

A further embodiment is especially advantageous in which the purge gas is introduced perpendicular and parallel to the wafer surface.

It has become evident in this case that it is especially advantageous when the gas flows around the contact needles of the test head in a laminar manner during the function check. Turbulence between the inert gas and the normal atmosphere, which is capable of falsifying the test results, is avoided by this means.

Another embodiment provides that the test head, connected to the measuring board, and the measuring board can have an aperture through which the nozzle for introducing the purge gas is passed. This design of the nozzle assures that a very high purge gas concentration is achieved in the area of the contact surfaces and the contact needle tips. In addition, the purge gas flows around the contact needles from above to the tips, so that deposits are avoided.

An embodiment has proven especially advantageous in this regard in which the aperture in the measuring board can be closed by the nozzle for introducing the purge gas, whereby a positive connection between the outer nozzle wall and measuring board is provided. Based on this nozzle design, the measuring board and nozzle form a barrier to the area above the measuring board, which is exposed to the air. Because the inflowing purge gas cannot escape upwards and also blockage in the downward direction is provided by the support device, an especially highly concentrated purge gas atmosphere forms below the measuring board in the area of the contact surfaces of the semiconductor circuits under test, and the contact needles.

The method for the testing of a plurality of integrated semiconductor circuits on wafers is carried out in the following steps. First, a wafer is positioned relative to a test head and contact needles by placing it on a support device, suctioning it there by a vacuum pump, and fixing it. In a second step, the integrated semiconductor circuits are contacted by the contact needles and thus an electrical connection is created between the wafer and a measuring board. After the check of a first electronic component, in a third step the wafer is moved by a grid dimension with the aid of the support device. In this case, the grid dimension depends in each case on the height of the semiconductor circuits under test. The steps “contacting of the semiconductor circuits” and “moving of the wafer” are repeated afterwards until the function check of all electronic components of the wafer has been completed. The wafer is then again removed from the testing device. Tests by the applicant have shown that the test method can be performed especially effectively and with cost reduction, when a purge gas is introduced onto the surface of the wafer through at least one nozzle on the device, whereby a sealing enclosure around the device is not used.

It is advantageous to introduce the purge gas here perpendicular to the wafer surface, because thereby a high purge gas concentration with the aforementioned positive effects is achieved with a very low purge gas volume.

It is also an advantage to introduce the purge gas onto the wafer surface even before the contacting of the semiconductor circuits or to heat the wafer before the contacting by a heatable support device, a so-called hot chuck. In this case, the adhesion of polar molecules to the wafer surface is reduced to a minimum and interfering molecules are removed by the purge gas before the contacting.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a section through a test head with contact needles during sampling of a wafer;

FIG. 2 shows a plan view of a test head with contact needles during sampling of a wafer;

FIG. 3 shows a perspective view of a test head with contact needles during sampling of a wafer; and

FIG. 4 shows a longitudinal section through a device for the testing of integrated semiconductor circuits on wafers.

### DETAILED DESCRIPTION

FIG. 1 shows a section through a test head 1 with contact needles 2 during sampling of a wafer 3, which lies on a support device 7. Test head 1 is attached to the bottom of a measuring board 4, which is shown only schematically, and connected electrically conductively to the measuring board 4. The measuring board 4 has a circular aperture 5, which enables a view from above of the area of the contact needles 2.

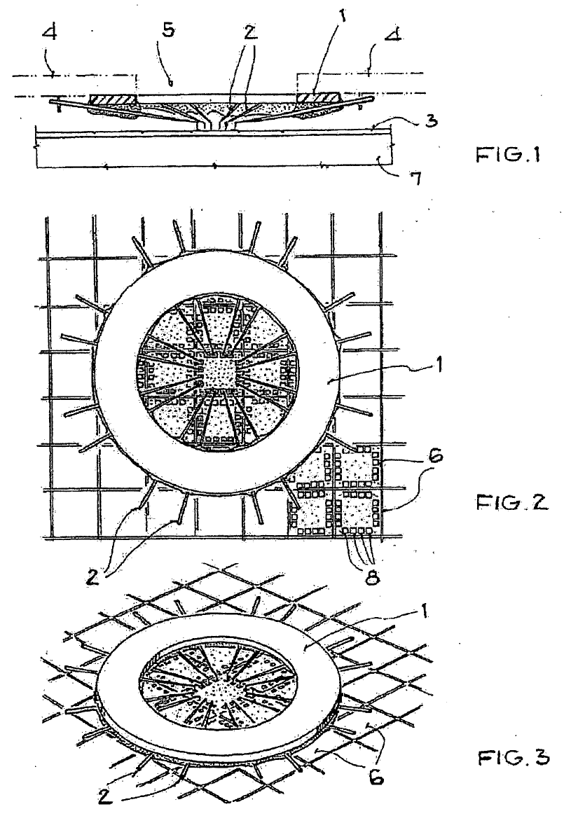

The top view of test head 1 in FIG. 2 and its perspective view in FIG. 3 schematically show several components of integrated semiconductor circuits 6 on wafer 3 and the arrangement of contact surfaces 8, which are sampled by contact needles 2. The arrangement and number of contact needles 2 and the associated circuit arrangement on the measuring board and the final shape of measuring board 4 itself hereby each depend on the electronic components under test.

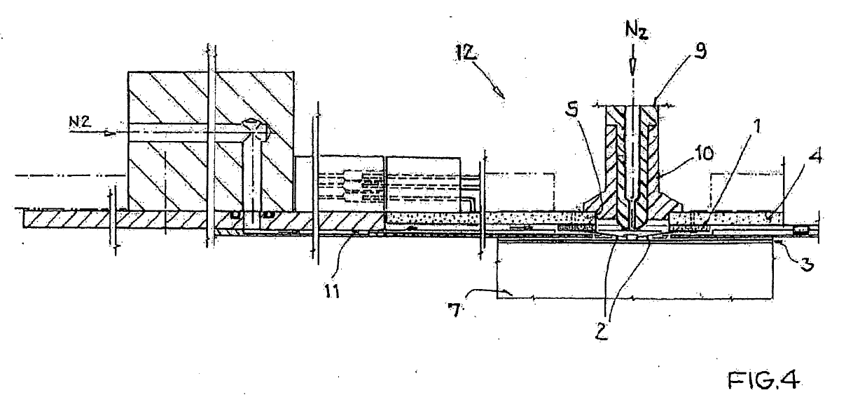

FIG. 4 shows a longitudinal section through a testing device 12. According to an embodiment, wafer 3 is heated during the function check by a heatable support device 7, a so-called hot chuck, as a result of which the adhesion of water on the surface of wafer 3 is reduced. Next, an inert gas flows through the area between measuring board 4 and support device 7 with the aid of at least one nozzle 11, whose outlet is disposed parallel to the wafer surface. This displaces the air and with it the highly reactive oxygen from device 12. Furthermore, a nozzle 9 is disposed on device 12, the nozzle 9 penetrates measuring board 4 and introduces the inert gas perpendicular to the wafer surface concentrated in the area of test head 1 above the contact needle tips. In this case, an adapter 10 is disposed at nozzle 9 that covers aperture 5 on the measuring board 4 and seals it simultaneously due to the positive fit between adapter 10 and measuring board 4. Thus, a space, which is closed from above and below and in which a highly concentrated purge gas atmosphere prevails, forms between measuring board 4 and support device 7. The measuring and control instruments, which are provided to control the purge gas feed depending on temperature or pressure, are not shown in FIG. 4, but permit control of individual nozzles 9, 11 independent of one another. The purging of the area around test head 1 with an inert gas with the aid of nozzle 9, 11 contributes to a high measuring reliability and to the avoidance of deposits at the contact needle tips.

Specifically in function checks that occur at high temperatures, the cooling effect achieved by the purging with a gas acts especially advantageously on the other components of device 12 and primarily on the electronic circuits on measuring board 4. Hereby, forgoing an enclosure for device 12 has a very positive effect, because the warm air can escape unimpeded.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A device for the testing a plurality of integrated semiconductor circuits on wafers, the device comprising:
a support device for receiving the wafer;
a measuring board having electronic circuit units for function testing of the integrated semiconductor circuits that are disposed on the wafers;
a test head that is connected to the measuring board, the test head having contact needles that form an electrical contact between the measuring board and the integrated semiconductor circuits; and
at least one nozzle for introducing a purge gas onto the wafer surface,
wherein the device is provided without a sealing enclosure, and
wherein the support device, measuring board, wafer, test head, and nozzle are exposed to the gas mixture of the atmosphere.

2. The device according to claim 1, wherein the purge gas is an inert gas or nitrogen.

3. The device according to claim 1, wherein the purge gas is introduced parallel to the wafer surface.

4. The device according to claim 1, wherein the purge gas is introduced perpendicular to the wafer surface.

5. The device according to claim 1, wherein the purge gas is introduced perpendicular and parallel to the wafer surface.

6. The device according to claim 4, wherein the measuring board has an aperture through which the nozzle extends.

7. The device according to claim 6, wherein the aperture in the measuring board can be substantially sealed by the nozzle, and wherein a positive connection between an outer nozzle wall and the measuring board is formed.

8. A method for testing a plurality of integrated semiconductor circuits on wafers with a device,
the method comprising the steps of:
positioning a wafer relative to a test head and contact needles;
contacting the integrated semiconductor circuits to provide an electrical connection between the wafer and a measuring board;
introducing a purge gas through at least one nozzle provided on the device, the purge gas being directed towards a surface of the wafer, wherein the purge gas is not contained by a sealing enclosure formed around the device, such that the purge gas dissipates into the ambient air.
moving the wafer by a grid dimension based on the size of the semiconductor circuits by a support device; and
removing the wafer from the device.

9. The method according to claim 8, wherein the purge gas is introduced perpendicular to the surface of the wafer.

10. The method according to claim 8, wherein the purge gas is introduced before the step of contacting.

11. The method according to claim 8, wherein the wafer is heated before the step of contacting by a heatable support device.

12. The device according to claim 1, wherein the support device controls a temperature of the wafer by heating or cooling.
